(19) United States
(12) Patent Application Publication
(10) Pub. No.: US 2023/0260105 A1
(43) Pub. Date: Aug. 17, 2023

(54) DEFECT DETECTION FOR SEMICONDUCTOR STRUCTURES ON A WAFER

(71) Applicant: Carl Zeiss SMT GmbH, Oberkochen (DE)

(72) Inventors: Thomas Korb, Schwaebisch Gmuend (DE); Philipp Huethwohl, Ulm (DE); Jens Timo Neumann, Aalen (DE)

(21) Appl. No.: 18/183,306

(22) Filed: Mar. 14, 2023

Related U.S. Application Data
(63) Continuation of application No. PCT/EP2021/075043, filed on Sep. 13, 2021.

(30) Foreign Application Priority Data
Sep. 15, 2020 (DE) 102020123979.3

(51) Int. Cl. G06T 7/00; G06T 5/20

(52) U.S. Cl. CPC G06T 7/001; G06T 5/20; G06T 2207/10056; G06T 2207/30148

(57) ABSTRACT

A method of a defect detection of a plurality of semiconductor structures arranged on a wafer includes obtaining a microscopic image of the wafer. The microscopic image depicts the plurality of semiconductor structures. The method also includes obtaining, from a database, fingerprint data for each base pattern class of a set of base pattern classes associated with respective one or more semiconductor structures of the plurality of semiconductor structures. The method further includes performing the defect detection based on the fingerprint data and the microscopic image.

### CROSS-REFERENCE TO RELATED APPLICATIONS

The present application is a continuation of, and claims benefit under 35 USC 120 to, international application PCT/EP2021/075043, filed Sep. 13, 2021, which claims benefit under 35 USC 119 of German Application No. 10 2020 123 979.3, filed Sep. 15, 2020. The entire disclosure of these applications are incorporated by reference herein.

### FIELD

Various examples of the disclosure generally relate to defect detection for semiconductor structures on a wafer. Various examples of the disclosure specifically relate to defect detection using a set of base pattern classes associated with the semiconductor structures on the wafer.

### BACKGROUND

Semiconductor structures are structured on wafers, e.g., silicon wafers, using lithography. Due to the complexity of the fabrication, defects can occur. Such defects can impair the functionality of semiconductor devices formed by the semiconductor structures. Accordingly, techniques have been devised to detect defects of semiconductor structures during or upon completion of fabrication (defect detection). In-line or end-of-line testing during or after fabrication is possible.

Two widely used techniques for defect detection in semiconductor manufacturing are die-to-die (D2D) defect detection and die-to-database (D2DB) defect detection. In both techniques, microscopic images depicting the dies (i.e., chip areas) on a wafer are acquired. It is then possible to compare such microscopic images with one or more reference images.

The one or more reference images correspond to the expected appearance of the semiconductor structures in absence of defects. For such comparisons, different metrics are known. For example, a comparison of the difference image against a threshold value can be implemented based on the metric and depending on an outcome of the threshold comparison, a defect can be reported.

D2D and D2DB defect detection mainly differ with respect to the sourcing or origin of the one or more reference images.

In D2D defect detection, the reference images are obtained from other regions of the wafer. For instance, a microscopic image of a first die can be compared against a reference microscopic image of one or more second dies. Another option is to compare three (or more) dies, without explicitly labeling one die as a reference: if two dies agree and the third die differs, the third die is reported as defective. Differently, for D2DB defect detection, the microscopic image is compared to a design template - e.g., a CAD layout - of the respective region of the semiconductor wafer. The CAD layout can be a collection of polygons, e.g., defined by nodes and edges.

It has been observed that a direct comparison between a microscopic image and a CAD layout may not yield useful results. For example, if polygons of a CAD layout are graphically represented, such graphic representation of the CAD layout lacks any features resulting from the fabrication process, e.g., lithography and/or etching and/or material deposition and/or grinding. For example, the fabrication process often tends to result in rounded corners; whereas such rounded edges are not reflected in the CAD layout. Other examples of features not reflected in a graphic representation of the CAD layout beyond corner rounding include edge roughness (e.g., caused by lithographic resist and/or etching). Furthermore, the transfer function of the imaging modality is not included in such a graphic representation of the CAD layout. A typical impact of the transfer function would be gray levels and noise caused by the imaging modality.

Thus, often, the CAD layout may be converted into a synthetic microscopic image that mimics influences of the fabrication process and/or the transfer function of the imaging modality. Such generation of a synthetic microscopic image based on the CAD layout typically includes: (i) simulating or emulating the lithography transfer function of the mask which is based on the CAD layout; (ii) simulating or emulating the etching process, e.g., based on the used etch gases and materials on the wafer; and (iii) simulating or emulating the microscopic image generation from a given material topography on the wafer, e.g., using an optical transfer function of the imaging modality. Running a full simulation of the steps (i) - (iii) has proven to be difficult and error prone. For example, detailed knowledge of the processing steps is not always available. Furthermore, detailed knowledge of the transfer function of the imaging modality is also not always available. Additionally, there may be effects of process variations which are hard to implement in a simulation.

An alternative approach for D2DB defect detection - not relying on the synthetic microscopic image - is to determine a mapping from the CAD layout to the microscopic image, e.g., by manually identifying, from the microscopic images, the typical corner rounding of the lithographic process which is to be applied to the CAD layout. For example, a user may parametrize the mapping by defining the gray levels appearing in the microscopic image for certain semiconductor structures. This corresponds to a type of visual comparison between a semiconductor structure in the CAD file and the actual SEM image. From this, an expert can deduce for the process and SEM at hand what is the foreground and the background gray level and use this for the heuristic mapping of a semiconductor structure in the CAD to its counterpart in the SEM image. Such an approach generally involves expert knowledge, typically for the domains of lithography and imaging. Accordingly, such an approach can be unreliable and subject to errors. Further, the mapping may have to be adapted or newly determined every time variations in the process occur or a change in the imaging modality is encountered.

Accordingly, such prior art techniques of D2DB defect detection can be error-prone and time-consuming. They may involve significant manual efforts. They may not be process stable, i.e., may involve adjustment or a new parameterization once the process changes. They may not be stable with respect to the imaging modality, i.e., may involve adjustment or a new parameterization once the imaging modality changes.

### SUMMARY

Accordingly, there is a desire for advanced techniques of defect detection for semiconductor structures on a wafer. For example, there is a desire for techniques that alleviate or mitigate at least some of the above-identified restrictions and drawbacks.

A method of a defect detection of a plurality of semiconductor structures is provided. The plurality of semiconductor structures is arranged on a wafer. The method includes obtaining a microscopic image of the wafer. The microscopic image depicts the plurality of semiconductor structures. The method also includes obtaining fingerprint data from a database. The fingerprint data is obtained for each base pattern class of a set of base pattern classes. Each base pattern class is associated with one or more respective semiconductor structures of the plurality of semiconductor structures. The method also includes performing the defect detection based on the fingerprint data and the microscopic image.

By using the fingerprint data for each base pattern class of the set of base pattern classes, an accurate defect detection can be provided for, even though it is not required to provide a mapping between a microscopic image and the design template such as a CAD layout.

A computer program or a computer-program product or a computer-readable storage medium including program code is provided. The program code can be executed by at least one processor. Upon executing the program code, the at least one processor performs a method of a defect detection of a plurality of semiconductor structures arranged on a wafer. The method includes obtaining a microscopic image of the wafer. The microscopic image depicts the plurality of semiconductor structures. The method also includes obtaining fingerprint data from a database. The fingerprint data is obtained for each base pattern class of a set of base pattern classes. Each base pattern class is associated with respective one or more semiconductor structures of the plurality of semiconductor structures. The method also includes performing the defect detection based on the fingerprint data and the microscopic image.

A device includes a control circuitry for a defect detection of a plurality of semiconductor structures arranged on a wafer. The control circuitry is configured to obtain a microscopic image of the wafer. The microscopic image depicts the plurality of semiconductor structures. The control circuitry is also configured to obtain fingerprint data from a database. The fingerprint data is obtained for each base pattern class of a set of base pattern classes. Each base pattern class is associated with one or more semiconductor structures of the plurality of semiconductor structures. The control circuitry is also configured to perform the defect detection based on the fingerprint data and the microscopic image.

A method of populating a database for a defect detection of a plurality of semiconductor structures arranged on a wafer is provided. The method includes obtaining a microscopic image of the wafer. The microscopic image depicts the plurality of semiconductor structures. The method includes for each base pattern class of a set of base pattern classes - each base pattern class of the set of base pattern classes being associated with respective one or more semiconductor structures of the plurality of semiconductor structures -, determining multiple microscopic image crops of the microscopic image. The microscopic image crops depict the one or more semiconductor structures of the plurality of semiconductor structures associated with the respective base pattern class. The method also includes determining fingerprint data for the respective base pattern class for each base pattern class of the set of base pattern classes. This is based on the respective multiple image crops. The method also includes populating the database with the fingerprint data for the base pattern classes.

A computer program or a computer-program product or a computer-readable storage medium includes program code. The program code can be loaded and executed by at least one processor. The at least one processor, upon loading and executing the program code, is configured to execute a method of populating a database for a defect detection of a plurality of semiconductor structures arranged on a wafer. The method includes obtaining a microscopic image of the wafer. The microscopic image depicts the plurality of semiconductor structures. The method also includes, for each base pattern class of a set of base pattern classes, each base pattern class of the set of base pattern classes being associated with the respective one or more semiconductor structures of the plurality of semiconductor structures, determining multiple microscopic image crops of the microscopic image. The microscopic image crops depict the one or more semiconductor structures of the plurality of semiconductor structures that are associated with the respective base pattern class. The method also includes determining, based on the respective multiple image crops, fingerprint data for the respective base pattern class for each base pattern class of the set of base pattern classes. The method also includes populating the database with the fingerprint data for the base pattern classes.

A device includes a control circuitry for populating a database for a defect detection for a wafer including a plurality of semiconductor structures. The control circuitry is configured to obtain a microscopic image of a wafer. The microscopic image depicts the plurality of semiconductor structures. The control circuitry is further configured, for each base pattern class of a set of base pattern classes (each base pattern class of the set of base pattern classes being associated with respective one or more semiconductor structures of the plurality of semiconductor structures), to determine multiple microscopic image crops of the microscopic image. The microscopic image crops depict the one or more semiconductor structures of the plurality of semiconductor structures associated with the respective base pattern class. The control circuitry is further configured to determine, for each base pattern class of the set of base pattern classes, fingerprint data for the respective base pattern class based on the respective multiple image crops. The control circuitry is further configured to populate the database with the fingerprint data for the base pattern classes.

It is to be understood that the features mentioned above and those yet to be explained below may be used not only in the respective combinations indicated, but also in other combinations or in isolation without departing from the scope of the disclosure.

### BRIEF DESCRIPTION OF THE DRAWINGS

FIG. 1 schematically illustrates a wafer including a plurality of semiconductor structures according to various examples.

FIG. 2 schematically illustrates a device configured to execute a defect detection according to various examples.

FIG. 3 is a flowchart of a method according to various examples.

FIG. 4 schematically illustrates a design template according to various examples.

FIG. 5 is a microscopic image associated with the design template of FIG. 4 according to various examples.

FIG. 6 schematically illustrates a defect in a semiconductor structure depicted by the microscopic image of FIG. 5 according to various examples.

FIG. 7 is a flowchart of a method according to various examples.

FIG. 8 schematically illustrates semiconductor structures associated with a base pattern class according to various examples.

FIG. 9 schematically illustrates a set of base pattern classes and arrangements of respective semiconductor structures in the microscopic image of FIG. 5 according to various examples.

FIG. 10 schematically illustrates determining multiple microscopic image crops for a base pattern class of the set of base pattern classes from the microscopic image of FIG. 5 according to various examples.

FIG. 11 is a flowchart of a method according to various examples.

FIG. 12 is a flowchart of a method according to various examples.

FIG. 13 is a flowchart of a method according to various examples.

FIG. 14 illustrates a workflow for defect detection according to various examples.

### DETAILED DESCRIPTION OF EXAMPLES

Some examples of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a general-purpose processor unit (CPU), a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a program code that is embodied in a non-transitory computer readable medium programmed to perform any number of the functions as disclosed.

In the following, examples of the disclosure will be described in detail with reference to the accompanying drawings. It is to be understood that the following description of examples is not to be taken in a limiting sense. The scope of the disclosure is not intended to be limited by the examples described hereinafter or by the drawings, which are taken to be illustrative only.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Hereinafter, techniques will be described that relate to a detection of defects in structures of semiconductor structures formed on a wafer. Defects can be detected for various kinds and types of semiconductor structures, e.g., semiconductor structures that are part of or implement semiconductor devices such as memory cells, logic cells, transistors, wires, vias, micro-electromechanical structures, etc.

According to various examples, a defect detection is facilitated. The defect detection is based on fingerprint data for base pattern classes associated with the semiconductor structures. The base pattern classes (which may also be referred to as base structure classes) can form a basis or building blocks that can be used to resemble the semiconductor structures across the wafer, e.g., by replicating and arranging and orientating the one or more semiconductor structures of each base pattern class accordingly.

As a general rule, the fingerprint data can enable to determine a representative appearance of semiconductor structures associated with the base pattern classes. Then, it is possible to compare the representative graphical appearance with at least parts of a microscopic image, e.g., microscopic image crops. The representative appearance can include impacts of the fabrication process and/or the imaging modality.

The fingerprint data can directly or indirectly define or even include an expected appearance of the semiconductor structures.

The fingerprint data can be obtained from examples showing the expected appearance of the semiconductor structures.

The fingerprint data can enable a comparison of an image crop depicting one or more semiconductor structures actually present on the wafer against a reference, i.e., the expected appearance of these one or more semiconductor structures.

The fingerprint data can be, at least to some extent, process stable. I.e., even in the presence of variations in the fabrication process and/or the imaging modality, it may still be possible to determine, based on the fingerprint data, a suitable representative appearance of semiconductor structures based on the fingerprint data. The fingerprint data can provide for a variance of the expected appearance due to tolerances of the fabrication process and/or variations of the imaging modality.

The fingerprint data of each base pattern class is associated with one or more semiconductor structures of the plurality of semiconductor structures of the wafer associated with that base pattern class. I.e., it is not required to provide fingerprint data for each one of the plurality of semiconductor structures; the fingerprint data is provided for each base pattern class. Thereby, the dimensionality can be reduced and the fingerprint data can be determined accurately, for each base pattern class. The set of base pattern classes can be smaller in size than the count of semiconductor structures or to be tested for defects. Such techniques are based on the finding that in typical design templates of wafers, repetitions of semiconductor structures occur. For example, a certain die including a set of semiconductor structures can be repeated multiple times across the wafer. There can also be repetitions of semiconductor structures within each die. Repetitions of semiconductor structures can be exploited to reduce the dimensionality of the set of base pattern classes if compared to the count of semiconductor structures on the wafer.

According to various examples, it is possible to automatically or semi-automatically determine the fingerprint data for the base pattern classes of the set of base pattern classes. For example, it would be possible to employ algorithms for one or more of the following tasks: image registration; classification of features and images; machine learning for defect detection; filters for defect detection; etc. By such techniques, it is possible to adequately detect defects for large microscopic images.

According to the techniques described herein, a design template - e.g., a CAD file - may be used. For example, it would be possible to use the design template when determining the base pattern classes. For instance, the base pattern classes may be determined when populating a database including the fingerprint data. Then, based on these base pattern classes that are determined based on the design template, the fingerprint data may be determined, and the database may be populated accordingly. The design template can also be used to determine microscopic image crops of a microscopic image, e.g., when determining the fingerprint data and/or in production mode when relying on the fingerprint data stored in the database to determine a representative appearance of semiconductor structures associated with the base pattern classes of the fingerprint data.

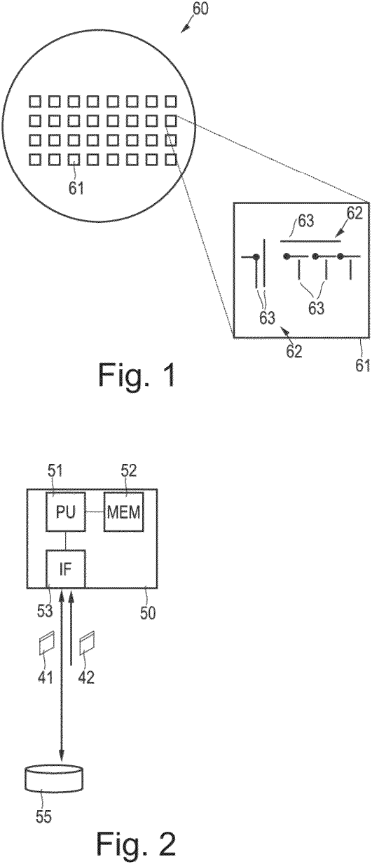

FIG. 1 schematically illustrates a wafer 60 including multiple dies 61. The die 61 is arranged repetitively. Each die 61 includes multiple semiconductor structures 62 (see inset of FIG. 1). Each semiconductor structure 62 can be formed by one or more elements 63, e.g., trenches, lines, dots, holes, etc. Each semiconductor structure 62 can be part of a semiconductor device, e.g., a memory cell, a logic element, or another functional unit.

FIG. 2 schematically illustrates a device 50 according to various examples. The device 50 includes a processing circuitry implemented by a processing unit 51 (simply, processor hereinafter) and a memory 52. The processor 51 can load and execute program code from the memory 52. The processor 51 is also coupled with a communication interface 53. The processor 51 can receive microscopic images 42 such as 2-D images or 3-D volumetric images, via the interface 53.

The microscopic images 42 may be received from a database or from an imaging device, e.g., a scanning electron microscope (SEM) or an optical microscope.

As a general rule, various imaging modalities are conceivable to provide the microscopic images 42, e.g., SEM, or optical imaging, UV imaging, atomic force microscopy, etc. He-particle imaging (HIM - Helium-Ion Microscopy) would be possible. A focused ion beam - SEM (or HIM, or generally any charged particle imaging) combination for 3-D volumetric imaging would be possible. X-ray-based tomography for 3D volumetric imaging would be possible as well.

The processor 51 can transmit or receive fingerprint data 41 to or from a database 55. While in FIG. 2 the database 55 is illustrated as a separate entity, it would be possible that the database 55 is stored in the memory 52.

The processor 51 can perform one or more of the following activities, based on the program code that is loaded from the memory 52 and upon executing the program code: populating the database 55 with the fingerprint data 41 for base pattern classes of a set of base pattern classes; determining the fingerprint data 41; determining the base pattern classes; obtaining the fingerprint data 41 from the database 55, e.g., depending on a wafer layout; performing a defect detection based on the fingerprint data 41; determining microscopic image crops of a microscopic image; etc. Hereinafter, details with respect to such functionality implemented by the processor 51 will be described.

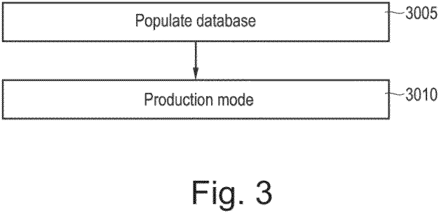

FIG. 3 is a flowchart of a method according to various examples. For instance, the method of FIG. 3 could be executed by the processor 51 of the device 50 (cf. FIG. 2). FIG. 3 illustrates the two stages of a defect detection. According to the techniques described herein, it is possible to execute both stages at box 3005 and box 3010, or only execute one of the two stages, e.g., at box 3005 or box 3010.

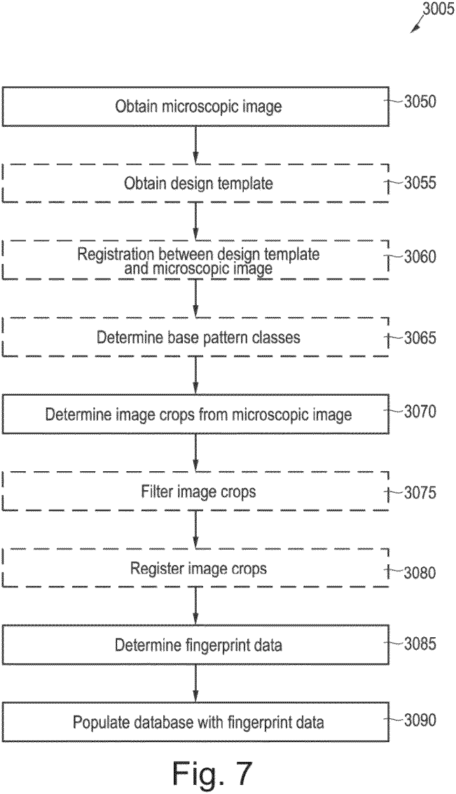

At box 3005, the database - e.g., the database 55 - is populated. This means that data that is suitable for implementing the subsequent execution of the algorithm determining whether or not the defect is present is provided to the database. According to examples described herein (e.g., cf. FIG. 7), fingerprint data - cf. FIG. 2: fingerprint data 41 - is determined for base pattern classes of a set of base pattern classes. This can be based on a design template of a wafer including the semiconductor structures. It may also be based on a microscopic image of the wafer, or other meta data, or a user selection.

Box 3005 thus corresponds to a preparation for the subsequent production stage, at box 3010.

At box 3010, data is obtained from the database; the data is for use in a defect detection. According to the examples described herein, the fingerprint data previously provided to the database can be read from the database. The fingerprint data can then be used to detect concrete instances of defects in a microscopic image of a wafer including multiple semiconductor structures.

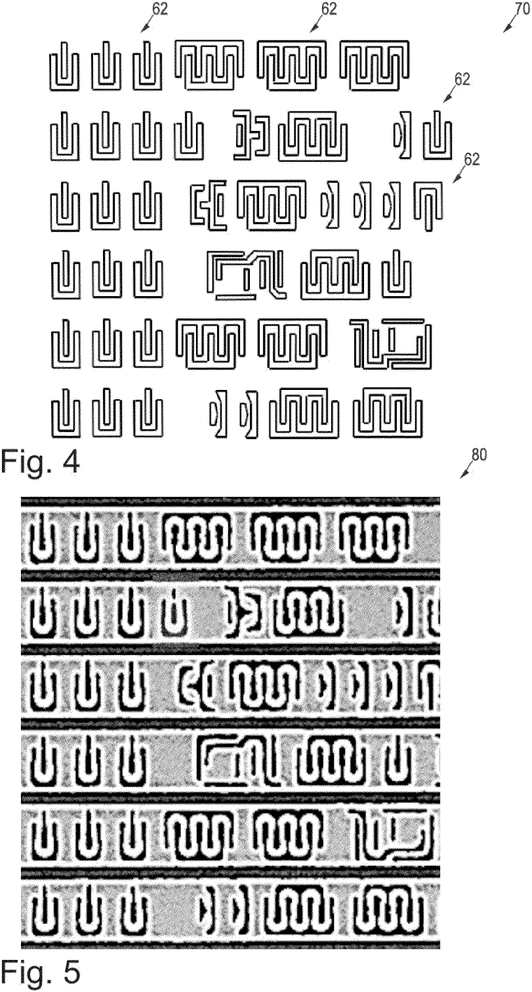

Such techniques are based on the finding that, oftentimes, it is not possible to immediately compare a design template such as a CAD layout with a microscopic image of a wafer. Details with respect to a CAD layout and the microscopic image are described in connection with FIG. 4 and FIG. 5.

FIG. 4 illustrates a design template, here in the form of a CAD layout 70, of semiconductor structures 62. The CAD layout 70 can be used for the fabrication process of the semiconductor structure 62, e.g., to define lithography masks and/or etching masks. The CAD layout 70 is formed by polygons. Thereby, the arrangement and/or orientation of the semiconductor structures 62 relative with each other is defined. The design template can also define the arrangement and/or orientation of the semiconductor structures 62 relative with respect to a wafer reference coordinate system.

FIG. 5 is a microscopic image 80 of the semiconductor structures 62 according to the CAD layout 70 of FIG. 4. While in the scenario of FIG. 5, the microscopic image 80 is acquired using SEM as imaging modality, the microscopic image 80 could be acquired using other imaging modalities in other examples.

As will be appreciated from a comparison between FIG. 4 in FIG. 5, the microscopic image 80 includes a number of features of the graphical appearance which are not included in the CAD layout 70, such as: grayscale; corner rounding; edge roughness. Such features in the graphical appearance are not indicative of defects of the semiconductor structures 62. Rather, such features are inherent to the fabrication process and the imaging using the imaging modality.

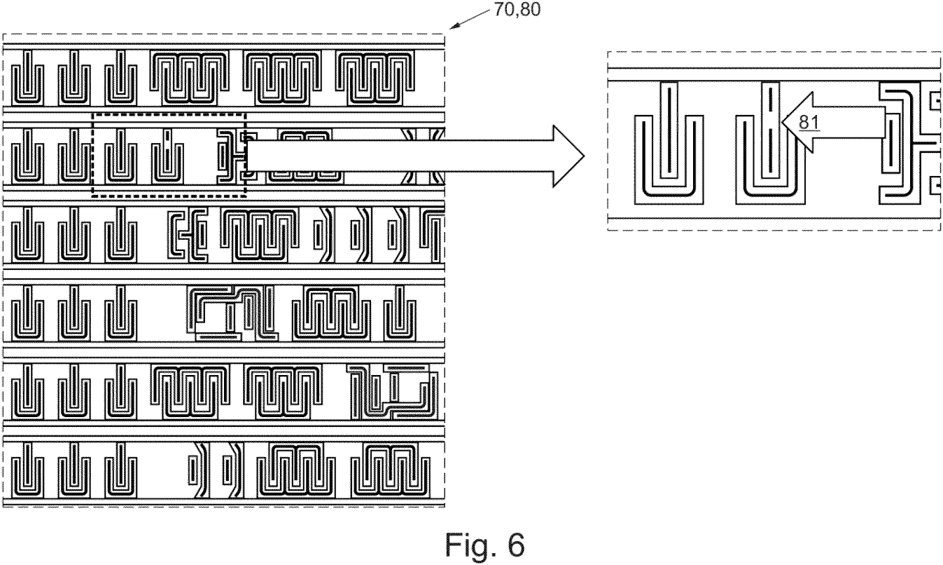

Nonetheless, there is a defect, namely a line break in the center line of the fourth semiconductor structure 62 (from the left side) in the second row. This defect 81 is illustrated in FIG. 6. FIG. 6 is an overlay of the CAD layout 70 onto the microscopic image 80.

Hereinafter, techniques will be described which enable to reliably detect such and other defects, even in view of the differences in the graphical appearances between the CAD layout 70 and the microscopic image 80.

FIG. 7 is a flowchart of a method according to various examples. For example, the method of FIG. 7 could be executed by the device 50 (cf. FIG. 2) or, more specifically, the processor 51 upon loading program code from the memory 52. The method of FIG. 7 enables to populate the database with fingerprint data (cf. FIG. 1: fingerprint data 41 and database 55). As such, the method of FIG. 7 implements box 3005 of FIG. 3. Optional boxes are labelled with dashed lines in FIG. 7.

At box 3050, a microscopic image is obtained (cf. FIG. 5: microscopic image 80). The microscopic image depicts a wafer including multiple semiconductor structures (cf. FIG. 1: wafer 60 and semiconductor structures 62). For illustration, the microscopic image could be received from an imaging device or could be loaded from a database or another memory.

At optional box 3055, a design template is obtained for the same wafer (cf. FIG. 4: CAD layout 70). The design template indicates the geometry of the semiconductor structures and their relative arrangement with respect to each other and, optionally, the relative arrangement with respect to the wafer, e.g., a wafer flat or wafer notch or another reference position on the wafer. The design template thus specifies semiconductor structures, as well as the relative arrangement of the semiconductor structures with respect to each other and optionally on the wafer. The orientation can be defined. The design template could be implemented by a CAD layout.

For instance, the design template could include multiple layers with polygons arranged on each layer. The multiple layers can correspond to different processing steps of a fabrication process. Not all polygons of the design template may be visible in the microscopic image, e.g., some lower layers of the semiconductor structures may be hidden by higher layers, or some layers may not have been manufactured yet at the stage of imaging the wafer by the imaging modality.

At optional box 3060, a registration is implemented between the microscopic image of box 3050 and the design template of box 3055. The registration specifies how the microscopic image is to be positioned and possibly also rotated and scaled to match the design template. This would enable to determine an overlay of the design template and the microscopic image (cf. FIG. 6). Conventional registration algorithms can be used.

For example, it would be possible to anchor dedicated markers in the CAD layout to instances of these markers in the microscopic image. Then, a coordinate transformation can be established between the CAD layout and the microscopic image or vice versa. Another example would include transforming polygons of the CAD layout into a synthetic image for registration, e.g., by filling the regions enclosed by the polygons with one gray value and the outside regions with another gray value. The gray values may be roughly determined by splitting the microscopic image histograms (i.e., distribution of brightness across pixels) into two modes and taking the mode centers as gray values. The synthetic image generated based on the CAD layout can then be registered to the microscopic image using, e.g., a normalized crosscorrelation. Even though the synthetic image may not be appropriate to perform defect detection, it may be suitable to be used in the registration. Registration can be performed on the full design template, or just using some portion of it.

At box 3065, base pattern classes can be optionally determined. In other examples, the base pattern classes can be predefined. For instance, the base pattern classes may be specified by the design template, e.g., as meta data.

As a general rule, a base pattern class can be associated with one or more semiconductor structures of the plurality of semiconductor structures of the wafer. Each base pattern class can specify one or more semiconductor structures of the plurality of semiconductor structures. The base pattern classes can specify the relative arrangement of multiple semiconductor structures with respect to each other. Thus, the base pattern class can be a building block defining one or more semiconductor structures that can be used to resemble the plurality of semiconductor structures on the wafer. The set of base pattern classes can describe a basis for resembling the plurality of semiconductor structures on the wafer.

As a general rule, various options exist for determining the base pattern classes, if desired. For example, similar and re-appearing polygons of the CAD layout can be grouped into base pattern classes. To make such a grouping, it would be possible to execute an unsupervised clustering of the various semiconductor structures as indicated by the design template of box 3055. Since the structures in the CAD are perfect and without any real-world variations, clustering can be accurately performed based on the design template. Another option would be to use clustering operating based on the microscopic image. A pre-trained classification algorithm may be used to determine the base pattern classes. It would also be possible to determine the base pattern classes based on input from a user.

As a general rule, in some examples it would be possible to only select a subset of the semiconductor structures in the design template to be included in the base pattern classes of the set of base pattern classes. This enables to limit the defect detection onto the subset of semiconductor structures, which can generally accelerate the throughput. For example, especially fragile semiconductor structures may be selected that are most likely root causes for failures of the functionality provided by the semiconductor devices.

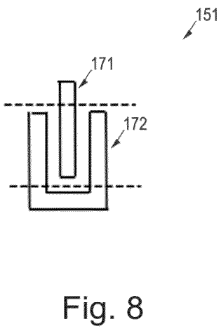

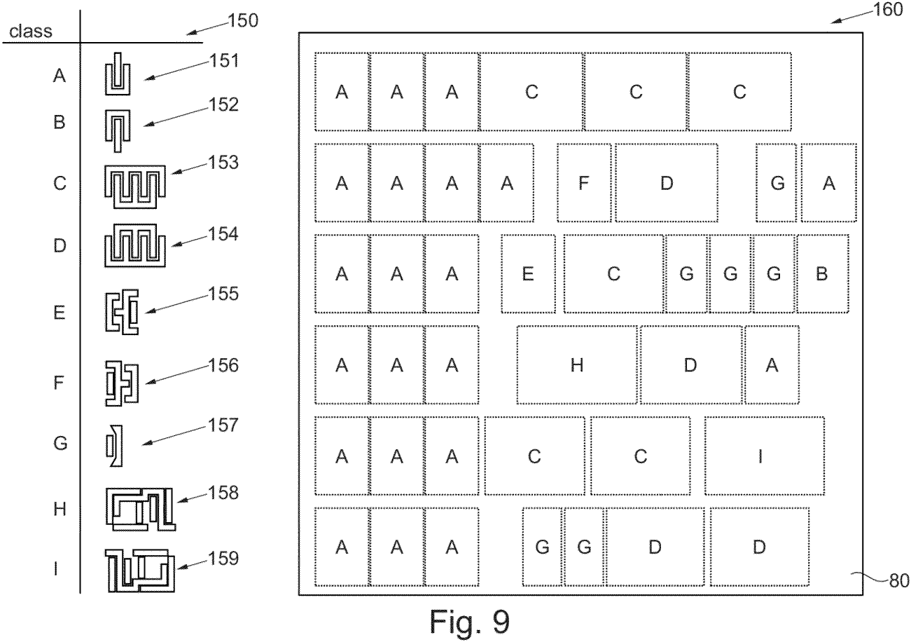

An example base pattern class 151 is illustrated in FIG. 8. The base pattern class 151 is associated with two semiconductor structures 171, 172 always occurring together. The semiconductor structure 171 is roughly I-shaped and the semiconductor structure 172 is roughly U-shaped. The semiconductor structure 171 and the semiconductor structure 172 are intertwined. This means that they cannot be separated using a horizontal or vertical cut (for example, vertical cuts are shown using the dashed lines in FIG. 8). Consequently, no rectangular axis parallel to a potential image crop of the microscopic image will show only semiconductor structure 172 which motivates defining the base pattern class 151 based on an aggregation of the intertwined semiconductor structures 171-172, to thereby be able to determine rectangular image crops.

Some examples of design rules for base pattern classes are: include intertwined semiconductor structures in a single base pattern class; form base pattern classes including not more than a threshold count of semiconductor structures; form base pattern classes including as few or as many as semiconductor structures as possible; include semiconductor structures associated with different semiconductor devices in different base pattern classes; include semiconductor devices associated with same semiconductor devices in the same pattern classes; semiconductor structures of a base pattern class can be cropped using a rectangular cropping mask; etc.. For example, a design rule for base pattern classes could be: select as few semiconductor structures as possible that can be cropped using a rectangular cropping mask.

The base pattern classes can be determined based on similarities between semiconductor structures (or associated polygons in the design template). Each semiconductor structure may be represented by a polygon. A polygon could be translated into a kind of vector, e.g., by turn left/right, proceed by x nm then turn left/right and so forth, until one reaches the starting node. Then the steps have to be cyclically permuted until some rule is fulfilled (e.g. starting with the shortest edge after a left/right turn) and by that one can generate comparable vectors which can be clustered using e.g. some kind of tree. These clusters can then correspond to the base pattern classes.

Then, at box 3070, it is possible to determine, for each base pattern class of the set of base pattern classes, multiple microscopic image crops of the microscopic image - as obtained at box 3050. The image crops depict the semiconductor structures that are associated with the base pattern classes.

For example, based on the coordinates in the CAD layout, polygons belonging to a given base pattern class can be identified. Then, based on the registration of box 3060, it would be possible to determine the regions to be cropped from the microscopic image. Rectangular crops are possible if intertwined semiconductor structures are considered per base pattern class. Where no registration is available, a similarity analysis between the respective base pattern class and the various regions of the microscopic images may be performed to define the areas to be cropped.

FIG. 9 illustrates an example of such cropping: there is a count of nine base pattern classes 151-159 in the respective set 150 (cf. CAD layout 70 of FIG. 4). The arrangement of these base pattern classes 151-159 in the microscopic image is illustrated by the arrangement 160. The arrangement 160 defines the position of each page pattern class 151-159 (labeled with “A” through “I”) within the microscopic image 80. The arrangement 160 can serve as a crop mask for the microscopic image. The cropping lines are illustrated with dotted lines in FIG. 9.

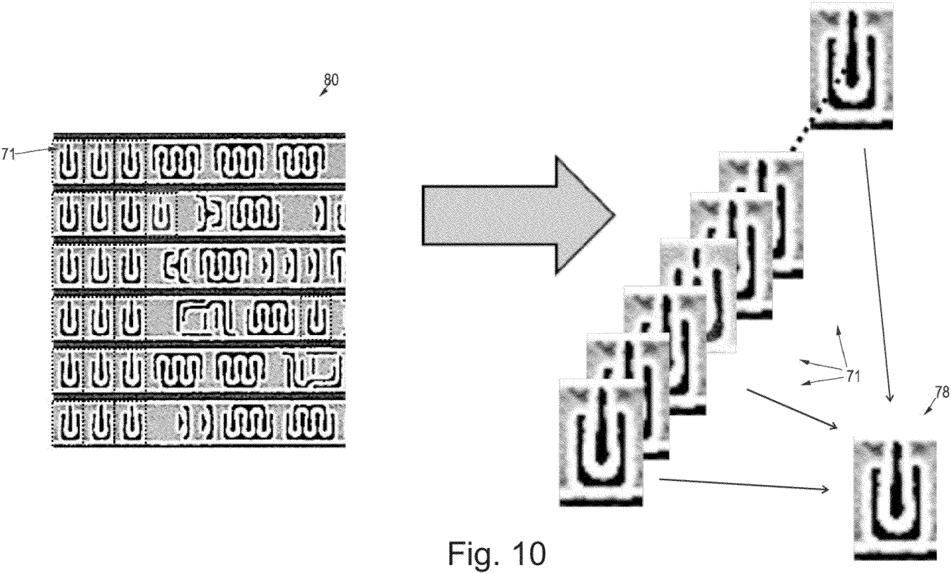

FIG. 10 illustrates the microscopic image crops 71 of the microscopic image 80 for the base pattern class 151. In this example, twenty microscopic image crops 71 are obtained.

Referring again to FIG. 7: it is then optional to filter the microscopic image crops 71 at box 3075. I.e., a subset of all image crops can be determined for subsequent processing and some microscopic image crops 71 may be removed, i.e., may not be part of the subset. This can be done to remove outliers.

As a general rule, various options are available to implement the filtering at box 3075. For example, the filtering could be implemented by calculating histograms and removing such microscopic image crops 71 that have histogram vectors that deviate beyond tolerance from an average/mean of the histograms. Alternatively or additionally, it would be possible to perform a registration between the image crops and then determine an average based on the image crops that are registered with each other. A pixel-wise average can be determined. Then, image crops that deviate significantly from that average can be removed.

Such filtering enables to remove outliers that are likely to show a defect. Thereby, the fingerprint data can be subsequently determined based on defect-free or mostly defect-free image crops. Thus, the quality of the fingerprint data can be improved. This makes the defect detection more accurate.

As a general rule, box 3075 may be selectively executed depending on one or more decision criteria. For example, implementing filtering at box 3075 may be of higher importance in scenarios in which the defect density increases. For instance, filtering at box 3075 may be of higher importance the higher the number of sample defects is compared to the total number of image crops. For example, if defects are sparse, then it may not be required to execute the filtering at box 3075. For example, it would be possible to determine or estimate a defect density and then selectively execute box 3075, i.e., the filtering, depending on the determined or estimated defect density. For instance, a manual inspection may be implemented to yield the defect density. A representative region of the wafer may be manually inspected. A defect density can be estimated, e.g., based on the maturity of the manufacturing process which was used to manufacture the wafer. For example, if there are only a few defects, then their impact on the determining of the fingerprint data may be negligible and separate filtering may not be required.

At box 3080, it is then optionally possible to register image crops associated with a given base pattern class with each other. For example, it is possible that the determining of the fingerprint data for the given base pattern class, subsequently executed at box 3085, is based on the registration. For example, a pixel-wise combination of the image crops may be determined, wherein corresponding pixels are determined based on the registration.

Another advantage of the registration optionally executed at box 3080 is that it gives access to the displacement errors.

Various reference techniques are available for implementing a registration. For example, it would be possible to select, for the registration, one of the image crops of the given base pattern class, e.g., randomly select one of the image crops. Then, it would be possible to perform the registration between the selected image crop of the multiple microscopic image crops associated with the given base pattern class with the remaining image crops of the multiple microscopic image crops associated with the given base pattern class. It would be then possible to perform a check of the quality of the registration. For example, if the registration quality is poor for the majority of the image crops - as would be expected if an image crop is selected that shows a defect - it would be possible to reselect another image crop and re-perform the registration to the remaining other image crops.

Note that while in the scenario of FIG. 7 box 3080 is executed after executing box 3075, it would also be possible that box 3080 is executed prior to execution of box 3075.

Next, at box 3085, fingerprint data is determined for each base pattern class of the set of base pattern classes. Then, at box 3090, it is possible to populate the database with the fingerprint data as determined at box 3085.

Next, details with respect to how the fingerprint data of the base pattern classes as determined at box 3085 will be described. Some implementations of the fingerprint data that can be used in the techniques disclosed herein are explained in TAB. 1.

TAB. 1

various options for implementing the fingerprint data

| | | |
|---|---|---|
| Example | Implementation of fingerprint data | Explanations |
| I | Representative microscopic image crop | For instance, a given fingerprint data can include a representative microscopic image crop 78 (cf. FIG. 10 ) of the one or more semiconductor structures associated with the respective base pattern class. For example, the representative microscopic image crop could be determined based on an average of the multiple microscopic image crops 71 taken from the microscopic image (cf. FIG. 10 ), or a subset thereof if, e.g., a filtering step 3075 has been applied. The average could be implemented in a pixel-wise combination of the respective pixel values, based on the registration (cf. FIG. 7 : box 3080). In such a scenario, it is not required to infer imaging data for comparison to the microscopic image or crops thereof; rather, the fingerprint data directly implements imaging data. This is different in the following examples II-IV. |
| II | Parameterization of graphical appearance | The fingerprint data can correspond to a parameterization. Based on such parameterization, it is possible to infer the graphical appearance, i.e., a synthetic representative microscopic image crop corresponding to the representative microscopic image crop as pre-provided according to example I. The parameterization can thus correspond to a rule set or mapping on how to derive the synthetic micro |
| | | scopic image crop of the one or more semiconductor structures associated with the respective base pattern class. The parameterization can thus implement a learned mapping how the one or more semiconductor structures - included in the design template - will look like after fabrication (lithography and/or etching) and considering the transfer function of the respective imaging modality. To determine parameterization weights - i.e., specifying parameter values of the ruleset - of the parameterization at box 3085, a comparison of the respective multiple microscopic image crops 71 (cf. FIG. 10 ) may be taken into consideration. For instance, a variability of the multiple microscopic image crops may be considered to determine a respective tolerance ranges specified by the parameterization. For instance, histograms of the multiple microscopic image crops may be determined and the parameterization may specify a respective reference histogram. It would be possible that the parameterization implemented by the fingerprint data outputs the synthetic representative microscopic image crop including variability or tolerance ranges. This can mimic variability in the fabrication process. Such tolerances can be implemented by ranges of the parameterization weights. A generative adversarial network (GAN) can be used. |
| III | Trained autoencoder neural network | A particular implementation of the parameterization of the graphical appearance according to example II would be a trained autoencoder neural network. Here, a microscopic image crop of the microscopic image - potentially including one or more defects -can be provided as an input to the trained autoencoder neural network. Then, the output corresponds to a synthetic representative microscopic image crop depicting one or more structures associated with the base pattern class. This is because the autoencoder neural network can be trained to not reconstruct defects or at least suppress defects The autoencoder neural network, as a general rule, can include an encoder neural network and a decoder neural network that are sequentially arranged. An input to the auto encoder neural network can be fed to the encoder neural network that determines an encoded representation of the input. The encoded representation of the input can be reduced in dimensionality vis-à-vis the input itself. The encoded representation can specify the presence or absence of certain features, i.e., correspond to a feature vector. The encoded representation can then be provided as an input to the decoder neural network. The decoder neural network can generate, based on the encoded representation, a decoded representation of the input. It is possible to train the autoencoder neural network using unsupervised learning, thereby determining the fingerprint data at box 3085. The autoencoder neural network can be trained based on microscopic image crops of the microscopic image |
| | | (cf. box 3070 of FIG. 7 ). The microscopic image crops can be extracted from the microscopic image based on the design template: the positions and arrangement of the one or more semiconductor structures associated with the respective base pattern class can be determined, to thereby define the crop position (cf. FIG. 7 , box 3070). During training, a loss function can be used as part of an iterative optimization of the weights of the encoder neural network, as well as the decoder neural network, the loss function penalizing differences between the input and the output, i.e., between a microscopic image crop that is input to the autoencoder neural network and the decoded representation of the microscopic image crop. Since defects are typically sparse, during the training process, the loss function is not significantly impacted by the presence or absence of defects. Accordingly, defects are not or only to a limited degree reproduced by the autoencoder neural network. It is possible to choose the complexity of the respective parameterization as low as possible so that the representative synthetic microscopic image obtained does not trigger detection of a defect in case the input image crop is defect-free. This would correspond to an end-to-end training of the machine-learning parameterization - e.g., implemented by the autoencoder - and the defect detection algorithm of the defect detection. |
| IV | Low-pass filter | The fingerprint data can specify one or more filter parameters of the low-pass filter. Then, a synthetic |
| | | representative microscopic image crop can be determined by providing, as an input, a respective microscopic image crop of the microscopic image depicting the one or more semiconductor structures associated with the respective base pattern class into the low-pass filter. The output of the low-pass filter can then be used as the representative synthetic microscopic image. Such techniques are based on the finding that typically defects are localized and have spatial extents that are smaller than the spatial extents of the host semiconductor structures on which the defects occur. Accordingly, by implementing the fingerprint data by appropriately configured low-pass filter, it is possible to derive the synthetic representative microscopic image of the one or more semiconductor structures associated with the respective base pattern class not showing defects or, at least, suppressing defects. |
| V | Decomposition into reduced basis set | It is possible to determine a basis adapted to the dominant contributions in the respective microscopic image crops. One example implementation would be a principal-component splitting (also referred to as principle component analysis, PCA) of the spatial frequencies of the respective microscopic image crop provided as the input. Then, it would be possible to retain only the first few dominant principal vectors. A cut-off principal vector may be defined by the respective principle component analysis. |
| | | These basis functions itself can be high frequent(cf. TAB. 1, example IV) - as one would expect e.g. for images of high frequency gratings. Here the dominant PCA mode / basis function would be the average of all the grating fingerprints being itself high frequent. The following PCA modes will then show the dominant observed deviations from the average. |

As described by TAB. 1, the fingerprint data can include or provide for a representative microscopic image of one or more semiconductor structures associated with the respective base pattern class, more specifically, a representative graphical appearance that is comparable with a respective microscopic image crop of a microscopic image. Examples II-V can be seen to all provide an optimized subspace basis expansion to be used to infer a representative microscopic image for the one or more semiconductor structures associated with a base pattern class, based on an image crop of a microscopic image depicting those one or more semiconductor structures. For examples II-V, it is possible to set the respective parameterization weights, e.g., for example IV filter cut-off frequencies or, in case of PCA - example V -, the number of base vectors to be included, or for example III the network design of the encoder neural network and/or the decoder neural network (neural network hyperparameters).

It would be possible to combine examples of TAB. 1 to form further examples. For example, a low-pass filter according to example IV may be combined with a PCA according to example V. It would also be possible to combine any one or more of the examples II-V with the example I, i.e., pre-filtering before generating an average.

It has been observed that for example I of TAB. 1, a fast and simple defect detection can be executed at production stage, because the representative microscopic image is readily available and does not need to be inferred based on the fingerprint data. At the same time, a flexibility in determining the fingerprint data may be limited, because typically only a single representative microscopic image is determined as the fingerprint data for each base pattern class. The flexibility is increased for example II-IV in that a respective synthetic representative microscopic image can be inferred based on the fingerprint data for each microscopic image crop of the microscopic image.

As will be appreciated from the above, it is possible using the techniques of FIG. 7 to populate the database with fingerprint data - thereby, implementing FIG. 3, box 3005 -, wherein the fingerprint data is configured to provide or infer (synthetic) representative microscopic image crops for the one or more semiconductor structures associated with the respective base pattern class. This corresponds to box 3005 of the method of FIG. 3, i.e., the preparation phase of the defect detection. Next, the production phase of the defect detection - according to box 3010 - will be explained.

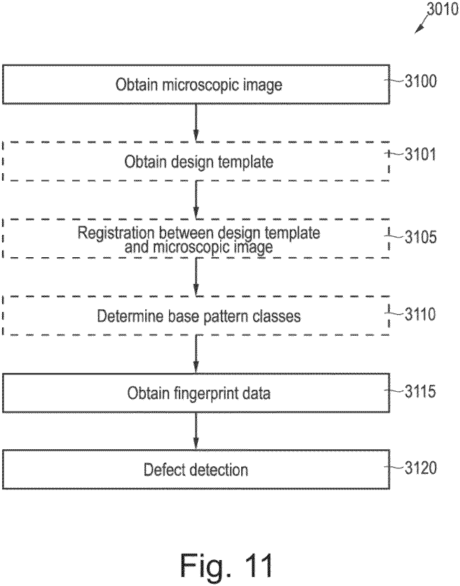

FIG. 11 is a flowchart of a method according to various examples. For example, the method of FIG. 11 could be executed by the device 50 of FIG. 2, more specifically by the processor 51 upon loading program code from the memory 52. The method of FIG. 11 implements the production phase according to box 3010 of FIG. 3. Optional boxes are labeled with dashed lines.

At box 3100, a microscopic image is obtained. For example, the microscopic image could be obtained from a database or from an imaging device. Various imaging modalities are conceivable, e.g.: SEM or another particle microscopy, light microscopy, etc. The wafer includes a plurality of semiconductor structures. Details with respect to the microscopic images have been described in connection with box 3050 and are applicable to box 3100, as well.

At optional box 3101, the design template of the wafer is obtained, e.g., a CAD file. For example, the fabrication of the semiconductor structures of the wafer can be based on the design template. In some options, it may not be required to obtain the design template. Then, the defect detection can be based on the microscopic image alone. Details with respect to the design template have been described above in connection with box 3055 and are applicable to box 3101, as well. The design template may be used to determine base pattern classes. The design template may be used to determine microscopic image crops of the microscopic image depicting the one or more semiconductor structures associated with the respective base pattern class.

At optional box 3105, a registration of the design template - e.g., the CAD layout (cf. FIG. 4: CAD layout 70) - and the microscopic image (cf. FIG. 5: microscopic image 80) can be performed. Box 3105 corresponds to box 3060 of the method of FIG. 7, i.e., can be similarly implemented.

Then, it is optionally possible to determine base pattern classes, at box 3110. For instance, a classification of the semiconductor structures of the wafer may be performed. A respective classification algorithm may be executed. The classification algorithm may be pre-trained, e.g., similarly to a classification algorithm that can be used at box 3065 of the method of FIG. 7. The classification algorithm may operate on the microscopic image. Where available, the classification algorithm may also operate based on the design template of box 3101. It would also be possible that the base pattern classes are determined based on meta data obtained from, e.g., the design template. For instance, the meta data could include an arrangement and optionally orientation of the semiconductor structures associated with the base pattern classes across the wafer (cf. FIG. 9). The classification algorithm may even operate on the microscopic image, e.g., in scenarios in which defects are localized and small and/or sparse if compared to the extents of the semiconductor structures associated with the base pattern classes. In other scenarios, it is possible that a set of base pattern classes predefined. Then it is not required to determine the base pattern classes

At box 3115, fingerprint data are obtained from the database. Accordingly, box 3115 is interrelated to box 3090 of the method of FIG. 7.

Then, at box 3120, a defect detection is performed based on the fingerprint data, as well as the microscopic image obtained at box 3100.

As a general rule, the defect detection performed at box 3120 can be based on comparisons between imaging data. Here, one or more defect detection algorithms may be executed, receiving multiple imaging data as an input. The comparison can be implemented based on an appropriate metric. For instance, a pixel-wise difference could be considered. If the comparison yields a significant difference between the multiple imaging data provided as an input, then a defect may be identified. The defect can be localized, e.g., if the comparison is implemented in a pixel-wise manner. In some examples, a machine-learning algorithm may be used to detect defects. The machine-learning algorithm may receive a concatenation of multiple images, e.g., of multiple microscopic image crops. Then, the machine-learning algorithm may detect differences between the multiple microscopic image crops. According to various examples, it would be possible that the machine-learning algorithm and an autoencoder neural network used to determine the fingerprint data are trained end-to-end.

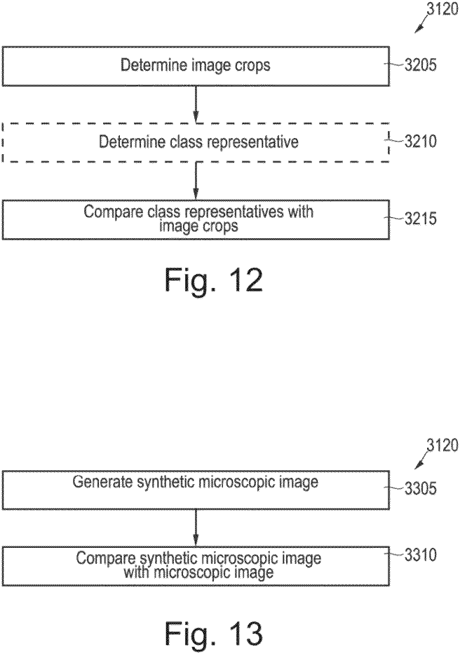

There are different options available for implementing the defect detection at box 3120 and two possibilities are illustrated in FIG. 12 and FIG. 13.

The method of FIG. 12 illustrates an example of the defect detection that is based on microscopic image crops of the microscopic images obtained at box 3100.

At box 3205, the microscopic image crops are determined. The microscopic image crops implement imaging data that can be provided to a defect detection algorithm of the defect detection.

These microscopic image crops depict the one or more semiconductor structures associated with the base pattern classes of the set of base pattern classes. Details with respect to these microscopic image crops 71 have been described above in connection with FIG. 8 and FIG. 10. As a general rule, multiple options are available for determining the boundaries of the image crops. For instance, in a scenario in which the design template is available (cf. FIG. 11: box 3101), the arrangement of the one or more semiconductor structures associated with the various base pattern classes can be determined based on the design template. In some options it would be possible that metadata is obtained that is already indicative of such arrangement. In yet further scenarios, it would be possible that the arrangement is determined based on the microscopic image. Once the arrangement of the one or more semiconductor structures associated with the various base pattern classes is known, the image crops can be generated by selecting the respective regions in the microscopic image.

Then, at box 3215, one or more class representatives of the respective base pattern class -implemented by or inferred from the fingerprint data of the respective base pattern class -are compared with the image crops.

In one example, the one or more class representatives that are obtained at box 3210 can be directly implemented by the fingerprint data. In other words, it would be possible that the fingerprint data include representative microscopic image crops (cf. FIG. 10: representative microscopic image crop 78) for the base pattern classes such that the defect detection is based on the comparison between the representative microscopic image crops and the microscopic image crops of the microscopic image (cf. TAB. 1: example I).

In other examples, it would be possible that it is desirable to determine the class representative at box 3210, prior to executing the comparison at box 3215. For example, it would be possible that the fingerprint data parametrizes a synthetic microscopic image crop depicting of the one or more semiconductor structures for each base pattern class (cf. TAB. 1: example II). Then, one or more synthetic representative microscopic image crops can be determined based on the microscopic image crops and the fingerprint data, for each base pattern class of the set of base pattern classes. The defect detection can then be based on a comparison between the microscopic image crops of the microscopic image and the synthetic representative microscopic image crops.

For instance, it would be possible that, per base pattern class, a single synthetic representative microscopic image is determined. In other examples, it would be possible that, per base pattern class, multiples synthetic representative microscopic image crops are determined, e.g., one for each image crop of the microscopic image and/or multiple synthetic representative microscopic images illustrating a variance in the imaging modality and/or the fabrication process where multiple synthetic representative image crops are determined, it would be possible that, per base pattern class, multiple comparisons are executed, i.e., one comparison per microscopic image crop with the respectively associated representative synthetic microscopic image crop.

For example, a scenario would be conceivable in which the fingerprint data includes trained autoencoder neural networks. Then, it would be possible to determine the synthetic representative microscopic image crops based on inputting the microscopic image crops of the microscopic image to the trained autoencoder neural network of a respective base pattern class (cf. TAB 1: example III).

It would also be possible that the one or more fingerprint data include a low-pass filter (cf. TAB. 1: example IV). Then, the synthetic representative microscopic image crops can be determined based on inputting the microscopic image crops of the microscopic image to the low-pass filter. Another option would be using PCA-based filter wherein the fingerprint data includes weights of the principle components of the PCA.

FIG. 13 illustrates a further technique for implementing the defect detection. Different to the implementation option of FIG. 12, in FIG. 13 the defect detection is not based on individual representative microscopic image crops depicting one or more semiconductor structures associated with the respective base pattern class, but is rather based on a large-area comparison based on imaging data that depicts semiconductor structures of multiple base pattern classes.

For example, sometimes it can be helpful to implement the defect detection not only using the semiconductor structures included in the design template, but also to inspect nominally empty regions of the dies or wafer. In such a scenario, it is helpful to generate a full synthetic microscopic image as a reference - i.e., not only an image crop. This is done at box 3305. Here, based on an arrangement of the base pattern classes (cf. FIG. 9: arrangement 160), the individual representatives of the base pattern classes - e.g., representative microscopic images provided by the fingerprint data or synthetic microscopic images inferred based on the fingerprint data - can be stacked together to form the synthetic microscopic image. The representatives of the base pattern classes can be placed according to their positions in the arrangement 160. For example, the entire design template may be used to determine such positions.

Then, at box 3310, the defect detection can be implemented based on a comparison between the synthetic microscopic image of the wafer and the microscopic image.

According to various examples, it would be possible that spaces in between the class representatives of the base pattern classes (e.g., representative microscopic image crops synthetically inferred from the fingerprint data or directly implemented by the fingerprint data) are filled with a background contrast. For example, the background contrast - e.g., certain value of a grayscale - can be determined based on the microscopic image as obtained at box 3100. For example, a position in the microscopic image may be selected that is outside any of the image crops.

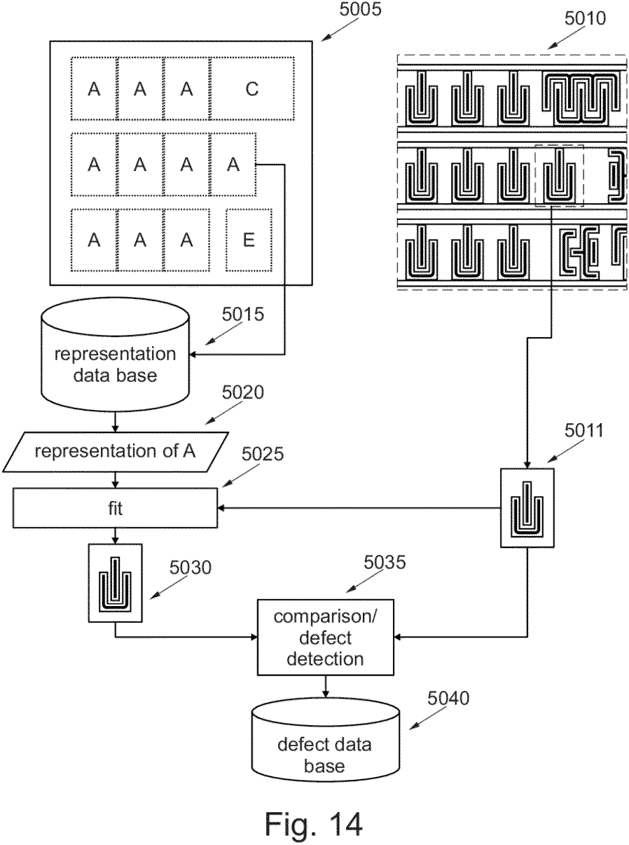

FIG. 14 is an example workflow for defect detection according to various examples. The workflow can implement the method of FIG. 3, as well as the methods of FIG. 7 and FIG. 11.

At 5005, fingerprint data is determined for multiple base pattern classes of a set of base pattern classes. Also, metadata of the arrangement of respective semiconductor structures associated with the base pattern classes in a design template of a wafer including multiple semiconductor structures is determined. Details with respect to such arrangement have been described in FIG. 9: arrangement 160. The determining fingerprint data has been described in connection with FIG. 10, with respect to a representative microscopic image crop 78. Details with respect to the fingerprint data have also been explained in connection with TAB. 1.

At 5015, the fingerprint data and the metadata is written to the database.

At 5010, a microscopic image is obtained, e.g., from a respective imaging modality.

Multiple microscopic image crops of the microscopic image are determined at 5011. Determining such image crops from the microscopic image has been described in connection with FIG. 10 and the microscopic image 80 and the microscopic image crops 71. The image crops can be determined based on the metadata written to the database at 5015 specifying a position of the respective structures associated with the base pattern classes on the wafer. A registration between the design template and the microscopic image can be used.

At 5020, the fingerprint data is obtained from the database 5015. Optionally, a fit of the image crops obtained at 5011 to the fingerprint data can be executed at 5025: this helps to infer synthetic microscopic image crops based on the fingerprint data (cf. TAB. 1, examples II-III; such fitting may not be required for TAB. 1, example I).

At 5030 a (synthetic) representative microscopic image crop is obtained from the fingerprint data. Then, a comparison can be executed at 5035 between the (synthetic) representative microscopic image crop and the microscopic image crops obtained from the microscopic image. This comparison is implemented by a defect detection algorithm. One or more defects can be detected and localized. The defects can be stored in the defect database at 5040.

Summarizing, above, techniques have been described that facilitate a defect detection without special knowledge on parameters such as the fabrication process and/or the imaging modality used to determine a microscopic image. The defect detection can be focused to a subset of the semiconductor structures for gaining throughput.

The techniques can be based to some smaller or larger degree on a design template. Thus, a D2DB defect detection may be implemented. For instance, it would be possible to use the design template during the training phase when determining the base pattern classes (cf. FIG. 7: box 3065) and when determining the image crops (cf. FIG. 7: box 3070). It would also be possible that the base pattern classes are (re-)determined during the production phase based on the design template. It would be possible that the microscopic image crops are determined by analyzing the design template, to find the one or more semiconductor structures associated with each base pattern class. The microscopic image crops used for the defect detection during the production phase can also be determined by analyzing the microscopic image itself, to find the one or more semiconductor structures associated with each base pattern class. In such a scenario, it may not be possible to verify an arrangement and/or orientation of the semiconductor structures in a wafer coordinate system.

Although the disclosure has been shown and described with respect to certain embodiments, equivalents and modifications will occur to others skilled in the art upon the reading and understanding of the specification. The present disclosure includes all such equivalents and modifications and is limited only by the scope of the appended claims.

1. A method, comprising:
obtaining a microscopic image of a wafer, the wafer comprising semiconductor structures, the microscopic image depicting the semiconductor structures;
obtaining, from a database, fingerprint data for each base pattern class of a set of base pattern classes associated with at least one of semiconductor structures; and
detecting a defect of the semiconductor structures based on the fingerprint data and the microscopic image.

2. The method of claim 1, wherein:
detecting the defect is based on microscopic image crops of the microscopic image of the wafer; and
for each base pattern class, the microscopic image crops class depict the at least one semiconductor structure associated with the base pattern class.

3. The method of claim 2, wherein:
for each base pattern class, the fingerprint data comprises a representative microscopic image crop of the at least one semiconductor structure associated with the base pattern class; and
detecting the defect comprises comparing the representative microscopic image crop of the base pattern classes and the microscopic image crops of the microscopic image.

4. The method of claim 2, wherein:
for each base pattern class, the fingerprint data parameterizes a respective synthetic representative microscopic image crop of the at least one semiconductor structure associated with the base pattern class;
for each base pattern class, the method further comprises determining, based on the respective microscopic image crops and the fingerprint data, at least one synthetic representative microscopic image crop depicting the semiconductor structure associated with the base pattern class; and
detecting the defect comprises comparing the microscopic image crops of the microscopic image and the synthetic representative microscopic image crops.

5. The method of claim 4, wherein for each base pattern class:
the fingerprint data comprises a trained autoencoder neural network; and
the at least one synthetic representative microscopic image crop is determined based on inputting the at least one microscopic image crop of the microscopic image to the trained autoencoder neural network.

6. The method of claim 4, wherein for each base pattern class:
the fingerprint data comprise a respective low-pass filter; and
the at least one synthetic representative microscopic image crop is determined based on inputting the at least one image crop of the microscopic image to the low-pass filter.

7. The method of claim 4, wherein for each base pattern class:
the fingerprint data comprises weight of principle components of a principle component analysis; and
the at least one representative microscopic image crop is determined based on inputting the image crops of the microscopic image to the principle component analysis.

8. The method of claim 2, further comprising determining the microscopic image crops based on a design template specifying an arrangement and orientation of the plurality of semiconductor structures.

9. The method of claim 1, further comprising based on the fingerprint data of the base pattern classes and an arrangement of the plurality of semiconductor structures, generating a synthetic microscopic image of the wafer, wherein detecting the defect comprises comparing the synthetic microscopic image of the wafer and the microscopic image.

10. The method of claim 9, further comprising:
determining, based on the fingerprint data and for each base pattern class, at least one representative microscopic image crop;
arranging the at least one representative microscopic image crop of the base pattern classes based on the arrangement, thereby generating the synthetic microscopic image; and
using a background contrast fill spaces in between the representative microscopic image crops in the synthetic microscopic image.

11. The method of claim 1, further comprising determining the set of base pattern classes based on at least one member selected from the group consisting of a design template of the plurality of semiconductor structures, metadata loaded from the database, a user selection, the microscopic image of the wafer, and a classification of structures of the semiconductor structures as depicted in the microscopic image.

12. The method of claim 1, further comprising associating at least one of the base pattern classes with multiple intertwined semiconductor structures.

13. One or more machine-readable hardware storage devices comprising instructions that are executable by one or more processing devices to perform operations comprising the method of claim 1.

14. A system comprising:
one or more processing devices; and
one or more machine-readable hardware storage devices comprising instructions that are executable by the one or more processing devices to perform operations comprising the method of claim 1.

15. A method, comprising:
obtaining a microscopic image of a wafer, the wafer comprising semiconductor structures, the microscopic image depicting the semiconductor structures;
for each base pattern class of a set of base pattern classes, each base pattern class of the set of base pattern classes being associated with respective semiconductor structure, determining multiple microscopic image crops of the microscopic image, the microscopic image crops depicting the at least one semiconductor structured associated with the respective base pattern class;
for each base pattern class of the set of base pattern classes, determining, based on the respective multiple microscopic image crops, fingerprint data for the respective base pattern class; and
populating a database with the fingerprint data for the base pattern classes.

16. The method of claim 15, wherein:
the fingerprint data of each base pattern class comprises a representative microscopic image crop of the at least one semiconductor structure associated with the respective base pattern class; and
the representative microscopic image crop of each base pattern class is determined based on an average of the respective multiple microscopic image crops depicting the at least one semiconductor structure associated with the respective base pattern class.

17. The method of claim 15, wherein:
the fingerprint data of each base pattern class comprises a parameterization of a synthetic representative microscopic image crop for the respective base pattern class; and
parameterization weights of the parameterization are determined based on a comparison of the multiple microscopic image crops depicting the at least one semiconductor structure associated with the respective base pattern class.

18. The method of claim 15, wherein:
the fingerprint data of each base pattern class comprise an autoencoder neural network configured to determine a synthetic representative microscopic image crop for the respective base pattern class; and
the autoencoder neural network is trained based on the multiple microscopic image crops depicting the at least one semiconductor structure associated with the respective base pattern class.

19. The method of claim 18, wherein the autoencoder neural network is trained end-to-end with a defect detection algorithm of the defect detection.

20. The method of claim 15, further comprising:
obtaining a design template of the plurality of semiconductor structures; and
based on the design template, determining at least one member selected from the group consisting of the set of base pattern classes and the multiple microscopic image crops.

21-26. (canceled)
